(19) United States
(12) Patent Application Publication
(10) Pub. No.: US 2025/0346997 A1
(43) Pub. Date: Nov. 13, 2025

(54) FILM FORMING METHOD AND FILM FORMING APPARATUS

(71) Applicant: Tokyo Electron Limited, Tokyo (JP)

(72) Inventor: Sena FUJITA, Nirasaki City (JP)

(21) Appl. No.: 19/274,978

(22) Filed: Jul. 21, 2025

Related U.S. Application Data
(63) Continuation of application No. PCT/JP2024/000788, filed on Jan. 15, 2024.

(30) Foreign Application Priority Data
Jan. 27, 2023 (JP) 2023-010861

(51) Int. Cl. C23C 16/455; C23C 16/04; C23C 16/08; C23C 16/28; C23C 16/458; C23C 16/52; C23C 16/56

(52) U.S. Cl. CPC C23C 16/45536; C23C 16/045; C23C 16/08; C23C 16/28; C23C 16/458; C23C 16/52; C23C 16/56

(57) ABSTRACT

A film forming method includes: preparing a substrate having a protrusion and a recess recessed from a top surface of the protrusion in a surface of the substrate; forming a first film containing boron more thickly on the top surface of the protrusion than on an inside of the recess; and after the forming of the first film, alternately or simultaneously supplying a raw material gas containing halogen and an element X other than the halogen and a reaction gas reacting with an adsorbate of the raw material gas to the surface of the substrate, thereby forming a second film containing the element X more thickly inside the recess than on the top surface of the protrusion.

### CROSS-REFERENCE TO RELATED APPLICATION

This application is a bypass continuation application of international application No. PCT/JP2024/000788 having an international filing date of Jan. 15, 2024 and designating the United States, the international application being based upon and claiming the benefit of priority from Japanese Patent Application No. 2023-010861, filed on Jan. 27, 2023, the entire contents of which are incorporated herein by reference.

### TECHNICAL FIELD

The present disclosure relates to a film forming method and a film forming apparatus.

### BACKGROUND

A method of forming a nitride film, which is described in Patent Document 1, includes a process of adsorbing chlorine gas to surfaces of a first underlying film and a second underlying film and a process of selectively forming the nitride film with respect to one of the first underlying film and the second underlying film, to which the chlorine gas is adsorbed.

### PRIOR ART DOCUMENTS

### Patent Documents

Patent Document 1: Japanese Patent Laid-Open Publication No. 2017-174919

### SUMMARY

According to one embodiment of the present disclosure, there is provided a film forming method, including preparing a substrate having a protrusion and a recess recessed from a top surface of the protrusion in a surface of the substrate; forming a first film containing boron more thickly on the top surface of the protrusion than on an inside of the recess; and after the forming of the first film, alternately or simultaneously supplying a raw material gas containing halogen and an element X other than the halogen and a reaction gas reacting with an adsorbate of the raw material gas to the surface of the substrate, thereby forming a second film containing the element X more thickly inside the recess on the top surface of the protrusion.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart showing a film forming method according to an embodiment.

FIG. 2 is a flowchart illustrating a specific example of the film forming method shown in FIG. 1.

FIG. 3 is a cross-sectional view illustrating an example of S101 to S103.

FIG. 4 is a cross-sectional view illustrating an example of S102 to S103 in a second first cycle.

FIG. 5 is a flowchart showing a film forming method according to a modification.

FIG. 6 is a view illustrating an example of S104 in a first second cycle and S102 to S103 in a second second cycle.

FIG. 7 is a flowchart showing a modification of S103.

FIG. 8 is a flowchart showing another modification of S103.

FIG. 9 is a cross-sectional view illustrating a film forming apparatus according to the embodiment.

FIG. 10 is an SEM photograph showing a substrate after a processing of example 1.

FIG. 11 is an SEM photograph showing a substrate after a processing of example 2.

FIG. 12 is an SEM photograph showing a substrate after a processing of example 3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments are described with reference to the accompanying drawings. Throughout the drawings, the same or corresponding members or components are denoted by the same or corresponding reference numerals, and redundant descriptions are omitted.

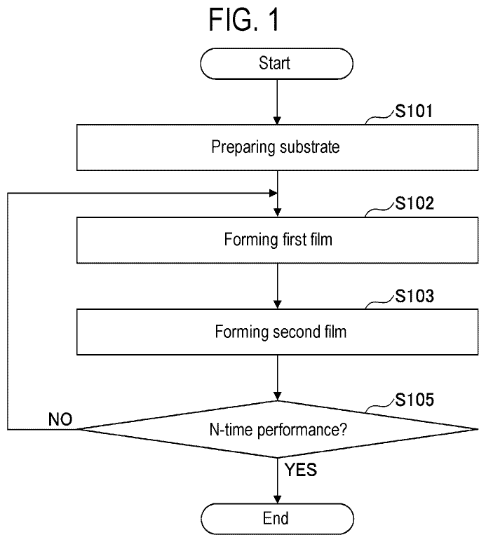

First, a film forming method according to an embodiment is described with reference to FIGS. 1 to 4. The film forming method includes, for example, steps S101 to S103 and S105 shown in FIG. 1. Step S104 will be described later. The film forming method may include steps other than the steps S101 to S103 and S105 shown in FIG. 1.

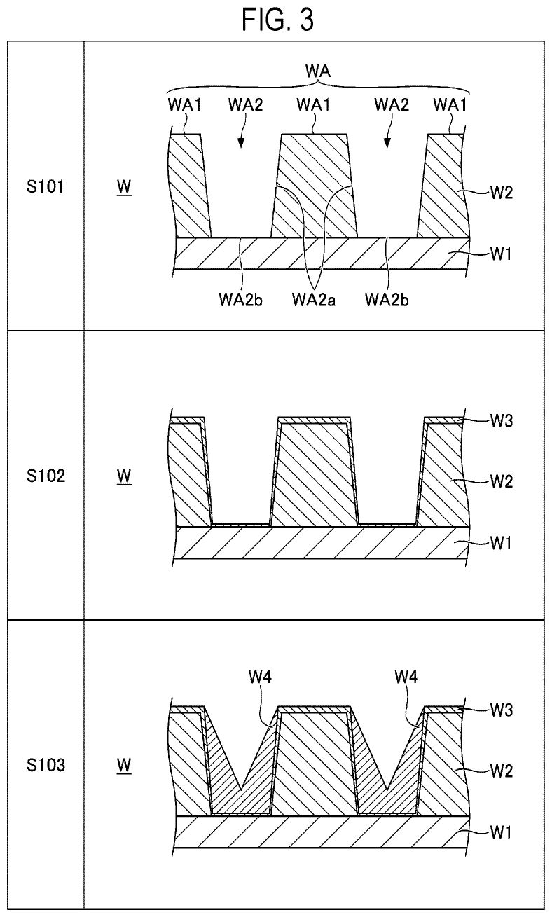

The step S101 includes preparing a substrate W (see FIG. 3). The substrate W includes, for example, a first underlying film W1 and a second underlying film W2 formed on the first underlying film W1. The first underlying film W1 and the second underlying film W2 are sequentially formed on a base substrate (not illustrated). The base substrate is a silicon wafer or a compound semiconductor wafer. The compound semiconductor wafer is, for example, a GaAs wafer, a SiC wafer, a GaN wafer, or an InP wafer.

The first underlying film W1 and the second underlying film W2 do not substantially contain boron (B). Not substantially containing B means that a B content is 0 atom % to 5 atom %. It is preferable that the B content in the first underlying film W1 and the second underlying film W2 is as low as possible. The first underlying film W1 and the second underlying film W2 may be any one of an insulating film, a conductive film, and a semiconductor film. Further, the first underlying film W1 may be omitted, and the second underlying film W2 may be formed directly on a surface of the base substrate.

The insulating film as the first underlying film W1 or the second underlying film W2 is not particularly limited, but is, for example, a SiO film, a SiN film, a SiOC film, a SiOCN film, an AlO film, a ZrO film, a HfO film, or a TiO film. Here, the SiO film means a film containing silicon (Si) and oxygen (O). An atomic ratio of Si and O in the SiO film is generally 1:2 but is not limited to 1:2. Similarly, the SiN film, the SiOC film, the SiOCN film, the AlO film, the ZrO film, the HfO film, and the TiO film also mean containing individual elements, and are not limited to the stoichiometric ratio. The insulating film is, for example, an interlayer insulating film. The interlayer insulating film is preferably a low dielectric constant (Low-k) film.

The semiconductor film as the first underlying film W1 or the second underlying film W2 is not particularly limited but is, for example, a Si film, a SiGe film, or a GaN film. The semiconductor film may be any one of a monocrystalline film, a polycrystalline film, and an amorphous film.

The conductive film as the first underlying film W1 or the second underlying film W2 is, for example, a metal film. The metal film is not particularly limited but is, for example, a Cu film, a Co film, a Ru film, a Mo film, a W film, or a Ti film. The conductive film may be a metal nitride film. The metal nitride film is not particularly limited but is, for example, a TiN film or a TaN film. Here, the TiN film means a film containing titanium (Ti) and nitrogen (N). An atomic ratio of Ti and N in the TiN film is generally 1:1 but is not limited to 1:1. Similarly, the TaN film also means containing individual elements, and is not limited to the stoichiometric ratio.

The substrate W has, on a surface thereof, protrusions WA1 and recesses WA2 recessed from a top surface of the protrusion WA1. The recess WA2 includes, for example, a side surface WA2a and a bottom surface WA2b. An opening pattern is formed in the second underlying film W2, so that the protrusion WA1 and the recess WA2 are formed. The top surface of the protrusion WA1 and the side surface WA2a of the recess WA2 are formed with the second underlying film W2, and the bottom surface WA2b of the recess WA2 is formed with the first underlying film W1. When the first underlying film W1 does not exist, the bottom surface WA2b of the recess WA2 is formed with the base substrate. Further, an opening of the second underlying film W2 penetrates the second underlying film W2, but may not penetrate the second underlying film W2. In this case, the bottom surface WA2b of the recess WA2 is formed with the second underlying film W2.

The step S102 includes forming a first film W3 containing boron more thickly on the top surface of the protrusion WA1 than on an inside of the recess WA2 (see FIG. 3). The first film W3 is formed by an atomic layer deposition (ALD) method or a chemical vapor deposition (CVD) method, and is formed by supplying a gas to the surface WA of the substrate W. The gas is more easily supplied to the top surface of the protrusion WA1 than the inside of the recess WA2. Thus, it is possible to form the first film W3 more thickly on the top surface of the protrusion WA1 than on the inside of the recess WA2. The first film W3 is formed along a protrusion-recess pattern, formed not only on the top surface of the protrusion WA1 but also inside the recess WA2, and formed more thickly on the top surface of the protrusion WA1 than on the inside of the recess WA2. Further, the first film W3 is formed on the entire surface of the protrusion-recess pattern, but may not be formed on a lower portion of the side surface WA2a of the recess WA2 and the bottom surface WA2b of the recess WA2.

A B content in the first film W3 is, for example, 20 atom % to 100 atom %, preferably 40 atom % to 100 atom %. The first film W3 is, for example, a B film, a BN film, a BNC film, a BO film, a BNOC film, a SiBN film, a SiBCN film, or a SiOBN film. Here, the BN film means a film containing boron (B) and nitrogen (N). An atomic ratio of B and N in the BN film is not limited to 1:1. Similarly, the BNC film and the like other than the BN film also mean containing individual elements, and are not limited to the stoichiometric ratio.

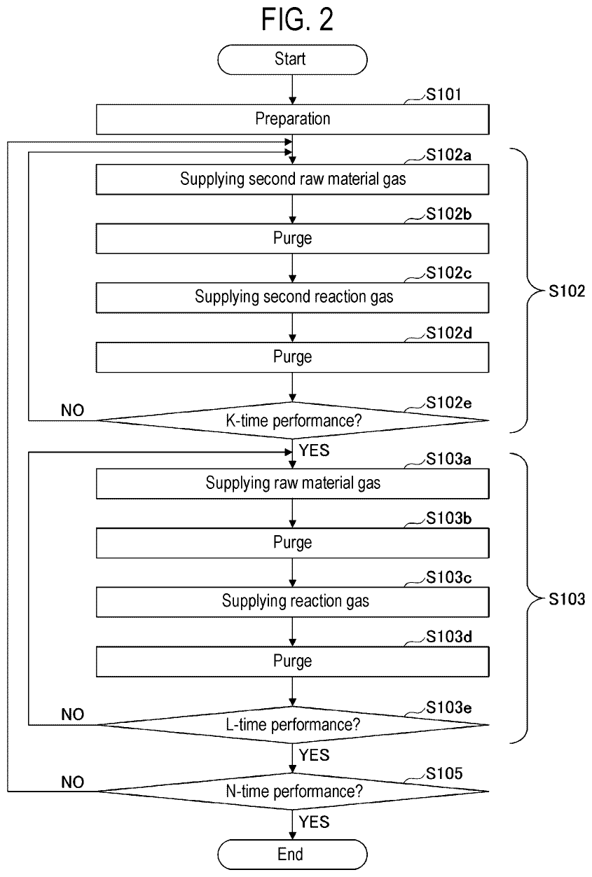

The step S102 includes, for example, steps S102a to S102e as illustrated in FIG. 2. Further, the step S102 may include the steps S102a and S102c, and may not include steps S102b, S102d, and S102e. The steps S102a to S102e are described below.

The step S102a includes supplying a second raw material gas to the surface of the substrate W. The second raw material gas contains boron. The second raw material gas includes, for example, trisdimethylaminoborane (TDMAB: C₆H₁₈BN₃). The second raw material gas may be supplied together with a dilution gas. The dilution gas is, for example, Ar gas or N₂ gas.

Further, the second raw material gas is not limited to including TDMAB, and may include, for example, diborane (B₂H₆), boron trichloride (BCl₃), boron trifluoride (BF₃), trisethylmethylaminoborane (C₉H₂₄BN₃), trimethylborane (C₃H₉B), triethylborane (C₆H₁₅B), cyclotriborazane (B₃N₃H₆), or the like.

The step S102b includes supplying a purge gas to the surface of the substrate W. The purge gas purges the surplus second raw material gas that has not been adsorbed to the surface WA of the substrate W in the step S102a. As the purge gas, for example, a rare gas such as Ar gas or N₂ gas is used.

The step S102c includes supplying a second reaction gas to the surface of the substrate W. The second reaction gas contains, for example, nitrogen and forms the first film W3 (e.g., a BN film) by nitriding the adsorbed second raw material gas. The second reaction gas includes, for example, a mixture of N₂ gas and H₂ gas, or NH₃ gas. The second reaction gas may be supplied together with a dilution gas. The dilution gas is, for example, Ar gas or N₂ gas.

Further, the second reaction gas may include at least one of a nitrogen-containing gas, an oxygen-containing gas, and a reducing gas. The nitrogen-containing gas forms a boron nitride film by nitriding the second raw material gas. The nitrogen-containing gas includes, for example, NH₃, N₂, N₂H₄, or N₂H₂. The oxygen-containing gas forms a boron oxide film by oxidizing the second raw material gas. The oxygen-containing gas includes, for example, O₂, O₃, H₂O, NO, or N₂O. The reducing gas forms a boron film by reducing the second raw material gas. The reducing gas includes, for example, H₂, SiH₄, or H₂S.

The step S102c may include plasmarizing the second reaction gas, and may include supplying the plasmarized second reaction gas to the surface WA of the substrate W. By plasmarizing the second reaction gas, it is possible to promote the formation of the first film W1.

In addition, the second reaction gas may be supplied not only in the step S102c but also in all of the steps S102a to S102d. However, the plasmarization of the second reaction is performed in only the step S102c. This is because a reaction of the second reaction gas with the second raw material gas adsorbed to the surface of the substrate W is promoted when the second reaction gas is plasmarized.

The step S102d includes supplying a purge gas to the surface of the substrate W. The purge gas purges the surplus second reaction gas that has not reacted with the surface WA of the substrate W in step S102c. As the purge gas, for example, a rare gas such as Ar gas or N₂ gas is used.

In the step S102e, it is checked whether or not the steps S102a to S102d have been performed K (K is an integer of 1 or more) times. K may be an integer of 2 or more, and the steps S102a to S102d may be repeatedly performed. A film thickness of the first film W3 on the top surface of the protrusion WA1 can be increased.

If a number of times the steps S102a to S102d are performed is less than K times (“NO” in step S102e), it means the film thickness of the first film W3 is less than a target value. Thus, the steps S102a to S102d are performed again. The target value of the film thickness of the first film W3 on the top surface of the protrusion WA1 is preferably 300 Å or less, more preferably 100 Å or less, further preferably 50 Å or less.

The first film W3 hinders formation of a second film W4 in the step S103, and is preferably formed thick enough not to expose the second underlying film W2 on the top surface of the protrusion WA1. It is considered that the first film W3 is formed into a film when nuclei grow on the surface of the second underlayer film W2 and adjacent nuclei make contact with each other. It is considered that until the nuclei have sufficient sizes, exposed portions of the second underlying film W2 exist in a dispersed manner. Thus, the film thickness of the first film W3 on the top surface of the protrusion WA1 is preferably 10 Å or more. It is considered that when the film thickness of the first film W3 is less than 10 Å, portions at which the second underlying film W2 is exposed exist, and therefore, an effect that hiders the formation of the second film W2 becomes weak.

On the other hand, if the number of times the steps S102a to S102d are performed reaches K times (“YES” in step S102e), it means the film thickness of the first film W3 on the top surface of the protrusion WA1 has reached the target value, and thus this step S102 ends.

In addition, a method of forming the first film W3, shown in FIG. 2, is the ALD method, but may be the CVD method. In the ALD method, the supply of the second raw material gas and the supply of the second reaction gas are alternately performed. On the other hand, in the CVD method, the supply of the second raw material gas and the supply of the second reaction gas are performed simultaneously.

In addition, the first film W3 may be a molecular film in which molecules are chemically adsorbed or physically adsorbed. The molecules are supplied to a substrate surface in a gaseous state. The gas has a functional group in the molecules, which is easily adsorbed to the substrate surface, and includes boron (B) in the molecules. The gas is supplied in a short time, so that it is possible to form the first film W3 more thickly on the top surface of the protrusion WA1 than on the inside of the recess WA2. The first film W3 may be formed by decomposition of the adsorbed molecules by heat of the substrate W.

The step S103 includes alternately or simultaneously supplying a raw material gas containing halogen and an element X other than the halogen and a reaction gas reacting with an adsorbate of the raw material gas, thereby forming the second film W4 containing the element X more thickly inside the recess WA2 than on the top surface of the protrusion WA1 (see FIG. 3). The second film W4 is hardly formed on the top surface of the protrusion WA1, and is selectively formed inside the recess WA2.

The step S103 includes, for example, steps S103a to S103e as illustrated in FIG. 2. Further, the step S103 may include the steps S103a and S103c, and may not include the steps S103b, S103d, and S103e. The steps S103a to S103e are described below.

The step S103a includes supplying a raw material gas to the surface of the substrate W. The raw material gas contains halogen and an element X other than the halogen. The halogen is fluorine, chlorine, bromine, or iodine. The element X is not particularly limited, but is preferably a metal element, more preferably a transition metal element. The element X is, for example, Ti, W, V, Al, Mo, Sn, Hf, Ta, Nb, Zr, In, Ga, or Sb. Specific examples of the raw material gas may include TiCl₄ gas, WCl₆ gas, VCl₄ gas, AlCl₃ gas, MoCl₅ gas, SnCl₄ gas, HfCl₄ gas, TaCl₅ gas, NbCl₅ gas, ZrCl₄ gas, InCl₃ gas, GaCl₃ gas, and SbCl₃ gas. The element X may be a semiconductor element, and specifically, may be Si or Ge. The raw material gas is a silicon halide gas or a germanium halide gas. Specific examples of the silicon halide gas may include SiCl₄ gas, SiHCl₃ gas, SiH₂Cl₂ gas, SiH₃Cl gas, Si₂Cl₆ gas, Si₂HCl₅ gas, Si₂Cl₃CH₃ gas, SiCl₃CCl₃ gas, SiCl₃CH₃ gas, SiH₂I₂ gas, or the like. Specific examples of the germanium halide gas may include GeCl₄ gas and the like. The raw material gas may be supplied together with a dilution gas. The dilution gas is, for example, Ar gas or N₂ gas.

The step S103b includes supplying a purge gas to the surface of the substrate W. The purge gas purges the surplus raw material gas that has not been adsorbed to the surface of the substrate W in step S103a. As the purge gas, for example, a rare gas such as Ar gas or N₂ gas is used.

The step S103c includes supplying a reaction gas to the surface of the substrate W. The step S103c may include plasmarizing the reaction gas, and may include supplying the plasmarized reaction gas to the surface of the substrate W. The reaction gas reacts with the element X included in the raw material gas adsorbed to the surface of the substrate W, thereby forming the second film W4 containing the element X. As the reaction gas, an oxygen-containing gas, a nitrogen-containing gas, or a hydrogen-containing gas may be used. The oxygen-containing gas contains oxygen and forms an oxide film of the element X. The oxygen-containing gas is, for example, O₂ gas, O₃ gas, CO₂ gas, N₂O gas, NO gas, or H₂O gas. The nitrogen-containing gas contains nitrogen, and forms a nitride film of the element X. The nitrogen-containing gas is, for example, NH₃ gas or N₂H₄ gas. The hydrogen-containing gas contains hydrogen, and forms a film (e.g., a metal film or a semiconductor film) using the element X as a major element. The hydrogen-containing gas is, for example, H₂ gas or H₂S gas. The reaction gas may be supplied together with a dilution gas. The dilution gas is, for example, Ar gas or N₂ gas.

Further, the reaction gas may be supplied not only in the step S103c but also in all of the steps S103a to S103d. However, the plasmarization of the reaction gas is performed in only the step S103c. This is because the reaction gas easily reacts with the raw material gas adsorbed to the surface of the substrate W when it is plasmarized.

The step S103d includes supplying a purge gas to the surface of the substrate W. The purge gas purges the surplus reaction gas that has not reacted with the surface of the substrate W in the step S103c. As the purge gas, for example, a rare gas such as Ar gas or N₂ gas is used.

In the step S103e, it is checked whether or not the steps S103a to S103d have been performed L (L is an integer of 1 or more) times. L may be an integer of 2 or more, and the steps S103a to S103d may be repeatedly performed. A film thickness of the second film W4 can be increased.

If a number of times the steps S103a to S103d are performed is less than L times (“NO” in step S103e), this means the film thickness of the second film W4 is less than a target value. Thus, the steps S103a to S103d are performed again. L is preferably 200 or more, more preferably 300 or more, further preferably 1,000 or more. L is preferably 10,000 or less.

On the other hand, if the number of times the steps S103a to S103d are performed reaches L times (“YES” in step S103e), the film thickness of the second film W4 has reached the target value, and thus this step S103 ends.

In addition, a method of forming the second film W4, shown in FIG. 2, is the ALD method, but may be the CVD method. In the ALD method, the supply of the raw material gas and the supply of the reaction gas are alternately performed. On the other hand, in the CVD method, the supply of the raw material gas and the supply of the reaction gas are performed simultaneously.

According to this embodiment, the step S103 includes forming the second film W4 more thickly inside the recess WA2 than on the top surface of the protrusion WA1 by hindering adsorption or dissociation of halide on the top surface of the protrusion WA1. In order to suppress the formation of the second film W4, it is important that adsorption of the raw material gas to the first film W3 is weak, and as a result, the raw material gas adsorbed on the first film W3 is desorbed without causing a film forming reaction (the formation of the second film W4). Alternatively, it is important that the adsorption of the raw material gas to the first film W3 does not occur or the dissociation of the raw material gas is difficult to occur on a surface of the first film W3.

It is considered that since the first film W3 contains boron, the adsorption of halide is weak on the first film W3, or the dissociation of halide is difficult to occur on the first film W3. This tendency is remarkable on the top surface of the protrusion WA1. This is because the film thickness of the first film W3 on the top surface of the protrusion WA1 is thicker than on the inside of the recess WA2. It is considered that, the film thickness of the first film W3 inside the recess WA2 is thinner, and exposed portions of the first underlying film W1 or the second underlying film W2 (portions not substantially containing boron) exist in a dispersed manner. Inside the recess WA2, the exposed portion of the first underlying film W1 or the second underlying film W2 (the portion not substantially containing boron) becomes a starting point of film formation, and the formation of the second film W4 progresses.

In addition, on the top surface of the protrusion WA1, the first film W3 is a continuous film and any exposed portions of the second underlying film W2 do not exist in this embodiment, but the exposed portions of the second underlying film W2 may exist. It is sufficient that an average film thickness of the first film W3 on the top surface of the protrusion WA1 is thicker than an average film thickness the first film W3 inside the recess WA2. The exposed portions of the second underlying film W2 may exist on the top surface of the protrusion WA1. It is sufficient that the formation of the second film W4 on the top surface of the protrusion WA1 starts later than the inside of the recess WA2.

In addition, halide such as TiCl₄ is more difficult to be decomposed by heat of the substrate W than an organic metal complex such as Ti[N(CH₃)₂]₄. When the raw material gas is decomposed after being adsorbed to the first film W3, the formation of the second film W4 progresses. Thus, in order to suppress the formation of the second film W4 on the top surface of the protrusion WA1, a gas containing halogen is suitable as the raw material gas for the second film W4.

In addition, in a plasma CVD method of plasmarizing both halide and a reaction gas, active species such as ions or radicals, generated by dissociating the halide, are generated. It is considered that the active species generated from the halide has a high reactivity, and hence a film forming reaction is easily caused not only inside the recess WA2 but also on the top surface of the protrusion WA1. Thus, it is preferable not to plasmarize the raw material gas, and it is important to use a thermal ALD method, a plasma ALD method, or a thermal CVD method.

In the step S103a to S103d, a temperature of the substrate W may be controlled to 100 degrees C. or more so as to promote dissociation of the raw material gas from the first film W3 on the top surface of the protrusion WA1. When the temperature of the substrate W is less than 100 degrees C., the raw material gas is physically adsorbed on the top surface of the protrusion WA1 without being sufficiently dissociated, and therefore, the second film W4 is formed even on the top surface of the protrusion WA1. The temperature of the substrate W is preferably 300 degrees C. or more. The temperature of the substrate W is preferably 800 degrees C. or less.

The step S105 includes checking whether or not a series of processes has been performed N times (N is an integer of 1 or more). The series of processes includes the formation of the first film W3 (the step S102) and the formation of the second film W4 (the step S103). The series of processes is also referred to as a first cycle. If a number of times the first cycle is performed is less than N times (“NO” in step S105), this means the film thickness of the second film W4 is insufficient, and therefore, the first cycle is performed again. On the other hand, if the number of times the first cycle is performed reaches N times (“YES” in step S105), this processing is ended. N is preferably an integer of 2 or more. When N is an integer of 2 or more, it is possible to increase the film thickness of the second film W4 while supplementing the first film W3.

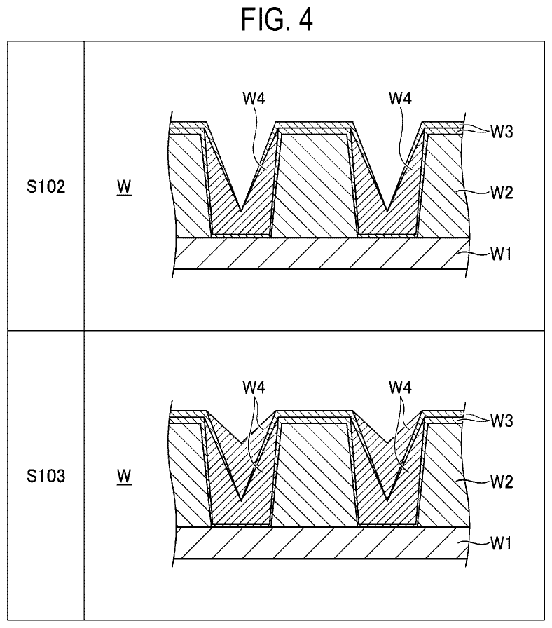

Next, a film forming method when N is an integer of 2 or more is described with reference to FIG. 4. When N is an integer of 2 or more, the first cycle is repeatedly performed a plural number of times. Like a first first cycle, in a second or subsequent first cycle, step S102 also includes forming a first film W3 containing boron more thickly on the top surface of the protrusion WA1 than on the inside of the recess WA2. The first film W3 is formed along the protrusion-recess pattern, formed not only on the top surface of the protrusion WA1 but also inside the recess WA2, and formed more thickly on the top surface of the protrusion WA1 than on the inside the recess WA2.

In addition, like the first first cycle, in the second or subsequent first cycle, step S103 includes alternately or simultaneously supplying a raw material gas containing halogen and an element X other than the halogen and a reaction gas reacting with an adsorbate of the raw material gas, thereby forming a second film W4 containing the element X more thickly inside the recess WA2 than on the top surface of the protrusion WA1. The second film W4 is hardly formed on the top surface of the protrusion WA1, and is selectively formed inside the recess WA2.

When N is an integer of 2 or more, as illustrated in FIG. 4, the first film W3 and the second film W4 are alternately stacked inside the recess WA2. Further, in FIG. 4, the first film W3 and the second film W4 are embedded in only a portion of the recess WA2, but N may be set such that the first film W3 and the second film W4 are embedded in the entire recess WA2. Further, when N is an integer of 2 or more, each of the processing conditions of the steps S102 and S103 may be the same each time or may be different each time.

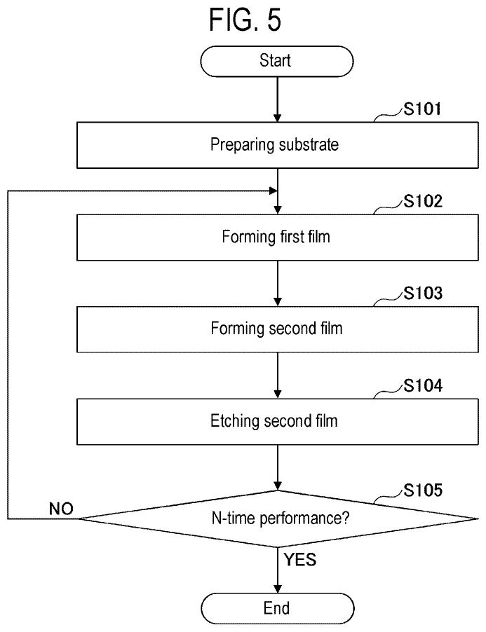

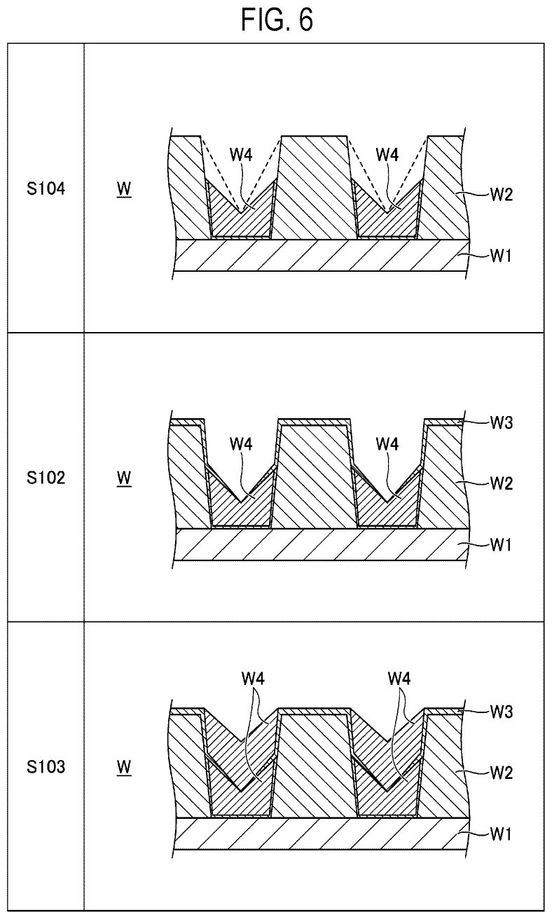

Next, a film forming method according to a modification is described with reference to FIGS. 5 and 6. Differences are mainly described below. The film forming method of this modification includes step S104 in addition to steps S101 to S103 and S105. A second cycle is composed of forming a first film W3 (the step S102), forming a second film W4 (the step S103), and etching the second film W4 (the step S104). Further, in the step S104, etching the first film W3 may also be performed in addition to the etching of the second film W4.

The step S104 includes supplying an etching gas to the substrate W after the step S103, thereby etching a portion of the second film W4. The second film W4 is formed more thickly inside the recess WA2 than on the top surface of the protrusion WA1, and may remain only inside the recess WA2 by removing the second film W4 on the top surface of the protrusion WA1 and in a vicinity thereof (an upper portion of the side surface WA2a).

The etching gas etches the second film W4, for example, from a state indicated by a broken line in FIG. 6 to a state indicated by a solid line in FIG. 6. The second film W4 may be planarized inside the recess WA2. It is possible to prevent a pair of left and right inclined surfaces constituting a cross-sectional V-shaped surface of the second film W4 inside the recess WA2 from closing to each other, thus preventing a space from remaining inside the second film W4.

In addition, when N is an integer of 2 or more, in a second or subsequent cycle, the step S104 may be performed after the step S102 and before the step S103. In that case, in the step S104 of an nth (n is an integer of 2 or more) cycle, etching of the first film W3 formed in the nth cycle and etching of the second film W4 formed in an (n−1)th cycle are continuously performed inside the recess WA2. It is sufficient that the first film W3 remains on the top surface of the protrusion WA1. Thereafter, the step S103 is performed.

Further, when N is an integer of 2 or more, the step S104 may be performed in at least one cycle. Further, when N is an integer of 2 or more, each of the processing conditions of the steps S102, S103, and S104 may be the same each time or may be different each time.

The etching gas is, for example, ClF₃ gas, Cl₂ gas, NF₃ gas, C₄F₈ gas, or the like. The etching gas may be plasmarized. Further, the etching gas may etch not only the second film W4 but also the first film W3.

When N is an integer of 2 or more in the step S105, the second cycle is repeatedly performed a plural number of times. When N is an integer of 2 or more, as illustrated in FIG. 6, the first film W3 and the second film W4 are alternately stacked inside the recess WA2. Further, in FIG. 6, the first film W3 and the second film W4 are embedded in only a portion of the recess WA2, but N may be set such that the first film W3 and the second film W4 are embedded in the entire recess WA2.

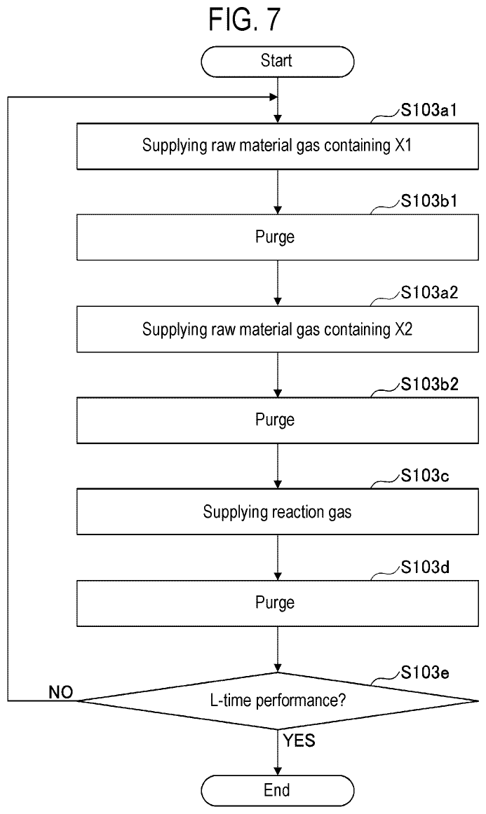

Next, a modification of the step S103 is described with reference to FIG. 7. Differences are mainly described below. As illustrated in FIG. 7, in step S103, a processing that sequentially includes supplying the raw material gas containing an element X1 as the element X (step S103a1), supplying the raw material gas containing, as the element X, an element X2 different from the element X1 (step S103a2), and supplying a reaction gas reacting with an adsorbate of the raw material gas (step S103c), in this order, is performed once or more.

In addition, supplying a purge gas (step S103bl) may be performed between the steps S103a1 and S103a2. Further, supplying a purge gas (step S103b2) may be performed between the steps S103a2 and S103c.

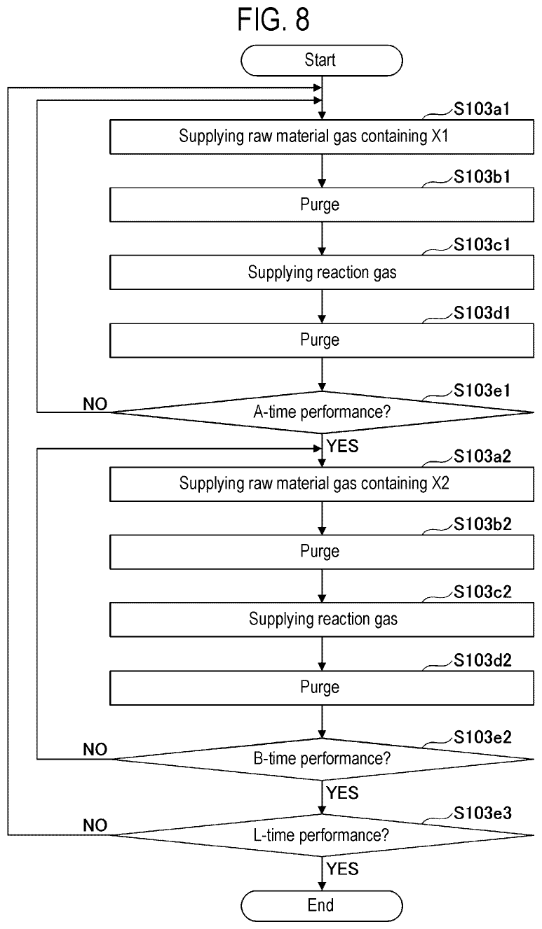

Next, another modification of the step S103 is described with reference to FIG. 8. Differences are mainly described below. As illustrated in FIG. 8, in step S103, a processing that sequentially includes supplying a raw material gas containing an element X1 as the element X (step S103al) and supplying a reaction gas reacting with an adsorbate of the raw material gas (step S103c1), in this order, is performed once or more. Further, in the step S103, a processing that sequentially includes supplying the raw material gas containing, the element X, an element X2 different from the element X1 (step S103a2) and supplying a reaction gas reacting with an adsorbate of the raw material gas (step S103c2), in this order, is performed once or more.

In addition, supplying a purge gas (step S103bl) may be performed between the steps S103al and S103cl. Further, immediately after the step S103c1, supplying a purge gas (step S103d1) may be performed. Further, supplying a purge gas (step S103b2) may be performed between the steps S103a2 and S103c2. Further, immediately after the step S103c2, supplying a purge gas (step S103d2) may be performed.

In step S103e1 of FIG. 8, A may be an integer of 1 or more or may be an integer of 2 or more. When A is an integer of 2 or more, the steps S103a1, S103b1, S103c1, and S103d1 are repeatedly performed a plural number of times. Further, in step S103e2 of FIG. 8, B may be an integer of 1 or more or may be an integer of 2 or more. When B is an integer of 2 or more, the steps S103a2, S103b2, S103c2, and S103d2 are repeatedly performed a plural number of times.

In FIGS. 7 and 8, any one of the element X1 and the element X2 is a metal element (preferably a transition metal element), and the other of the element X1 and the element X2 is a semiconductor element. Further, in FIGS. 7 and 8, a combination of the element X1 and the element X2 is not particularly limited. The combination of the element X1 and the element X2 may be a combination of metal elements or a combination of semiconductor elements. In any case, the second film W4 containing the element X1 and element X2 is obtained. The element X may include an element X3 different from the elements X1 and X2, or may include three or more elements different from one another. Supplying a raw material gas containing the element X3 may be performed.

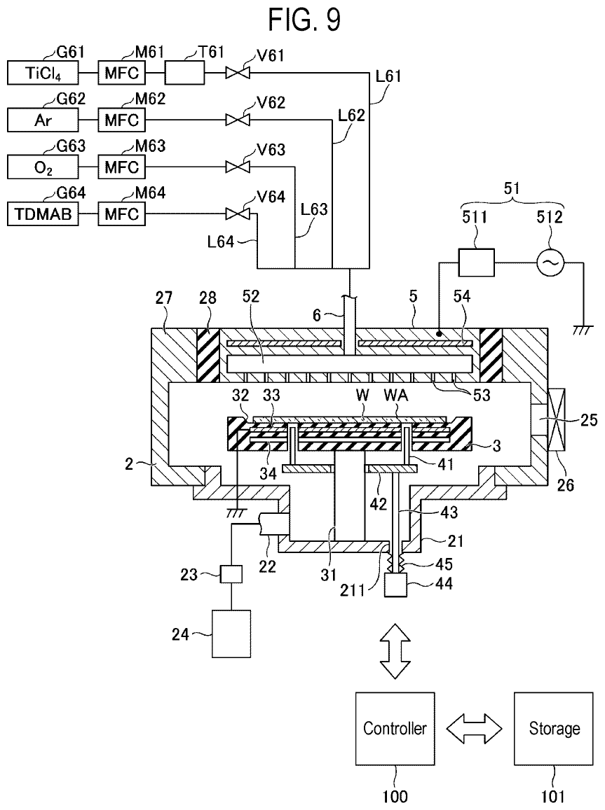

Next, a film forming apparatus 1 according to the embodiment is described with reference to FIG. 9. The film forming apparatus 1 includes a substantially cylindrical airtight processing container 2. An exhaust chamber 21 is provided in a central portion of a bottom wall of the processing container 2. The exhaust chamber 21 has, for example, a substantially cylindrical shape that protrudes downward. An exhaust pipe 22 is connected to the exhaust chamber 21, for example, on a side surface of the exhaust chamber 21.

An exhauster 24 is connected to the exhaust pipe 22 via a pressure adjuster 23. The pressure adjuster 23 includes, for example, a pressure adjustment valve such as a butterfly valve. The exhaust pipe 22 is configured such that a pressure inside the processing container 2 can be reduced by the exhauster 24. A transfer port 25 is provided in a side surface of the processing container 2. The transfer port 25 is opened and closed by a gate valve 26. Loading/unloading of a substrate W between an interior of the processing container 2 and a transfer chamber (not illustrated) is performed through the transfer port 25.

A stage 3 is provided in the processing container 2. The stage 3 is a holder that holds the substrate W horizontally such that a surface WA of the substrate W faces upward. The stage 3 has a substantially circular shape in a plan view and is supported by a support 31. A substantially circular recess 32 is formed in a surface of the stage 3 to place therein the substrate W having a diameter of, for example, 300 mm. The recess 32 has an inner diameter slightly larger than the diameter of the substrate W. A depth of the recess 32 is substantially the same as, for example, a thickness of the substrate W. The stage 3 is made of a ceramic material such as aluminum nitride (AlN). Further, the stage 3 may be made of a metallic material such as nickel (Ni). Instead of the recess 32, a guide ring configured to guide the substrate W may be provided at a peripheral edge of the surface of the stage 3.

In the stage 3, for example, a grounded lower electrode 33 is embedded. A heating mechanism 34 is embedded below the lower electrode 33. The heating mechanism 34 heats the substrate W placed on the stage 3 to a set temperature by being fed with power based on a control signal from a controller 100. When the entire stage 3 is made of metal, the entire stage 3 functions as a lower electrode, and thus it is unnecessary to embed the lower electrode 33 in the stage 3. The stage 3 is provided with a plurality of (for example, three) lifting pins 41 configured to hold and vertically move the substrate W placed on the stage 3. A material of the lifting pins 41 may be, for example, ceramic, such as alumina (Al₂O₃) or quartz. Lower ends of the lifting pins 41 are installed on a support plate 42. The support plate 42 is connected to a lifting mechanism 44 provided outside the processing container 2 via a lifting shaft 43.

The lifting mechanism 44 is installed, for example, below the exhaust chamber 21. A bellows 45 is provided between the lifting mechanism 44 and an opening 211 for the lifting shaft 43, which is formed in a lower surface of the exhaust chamber 21. The support plate 42 may have a shape that can be moved vertically without interfering with the support 31 of the stage 3. The lifting pins 41 are configured to be movable vertically between above the surface of the stage 3 and below the surface of the stage 3 by the lifting mechanism 44.

A gas supply 5 is provided on a ceiling wall 27 of the processing container 2 via an insulator 28. The gas supply 5 forms an upper electrode and faces the lower electrode 33. A radio-frequency power supply 512 is connected to the gas supply 5 via a matcher 511. High-frequency power of 100 kHz to 2.45 GHz, preferably 450 kHz to 100 MHz, is supplied to the upper electrode (the gas supply 5) from the radio-frequency power supply 512, so that a radio-frequency electric field is generated between the upper electrode (the gas supply 5) and the lower electrode 33 to generate capacitively coupled plasma. A plasma generator 51 includes the matcher 511 and the radio-frequency power supply 512. Further, the plasma generator 51 is not limited to the capacitively coupled plasma, and may generate any plasma such as inductively coupled plasma or remote plasma.

The gas supply 5 includes a hollow gas supply chamber 52. In a bottom surface of the gas supply chamber 52, a plurality of holes 53 for dispersing and supplying a processing gas into the processing container 2 are, for example, arranged evenly. A heating mechanism 54 is embedded in the gas supply 5, for example, above the gas supply chamber 52. The heating mechanism 243 is heated to a set temperature by being fed with power from a power supply (not illustrated) based on a control signal from the controller 100.

A gas supply path 6 is provided in the gas supply chamber 52. The gas supply path 6 communicates with the gas supply chamber 52. On an upstream of the gas supply path 6, gas sources G61, G62, G63, and G64 are connected to gas lines L61, L62, L63, and L64, respectively. Further, the number and gas species of gas sources are not limited to those illustrated herein.

The gas source G61 is a gas source of TiCl₄ and is connected to the gas supply path 6 via the gas line L61. In the gas line L61, a mass flow controller M61, a storage tank T61, and a valve V61 are sequentially provided from a side of the gas source G61. The mass flow controller M61 controls a flow rate TiCl₄ gas flowing in the gas line L61. The storage tank T61 stores the TiCl₄ gas supplied from the gas source G61 via the gas line L61 in a state in which the valve V61 is closed, thereby increasing a pressure of the TiCl₄ gas in the storage tank T61. The valve V61 performs supply and cutoff of the TiCl₄ gas to the gas supply path 6 by opening and closing operations thereof.

The gas source G62 is a gas source of Ar and is connected to the gas supply path 6 via the gas line L62. In the gas line L62, a mass flow controller M62 and a valve V62 are sequentially provided from a side of the gas source G62. The mass flow controller M62 controls a flow rate of Ar gas flowing in the gas line L62. The valve V62 performs supply and cutoff of the Ar gas to the gas supply path 6 by opening and closing operations thereof.

The gas source G63 is a gas source of O₂ and is connected to the gas supply path 6 via the gas line L63. In the gas line L63, a mass flow controller M63 and a valve V63 are sequentially provided from a side of the gas source G63. The mass flow controller M63 controls a flow rate of O₂ gas flowing in the gas line L63. The valve V63 performs supply and cutoff of the O₂ gas to the gas supply path 6 by opening and closing operations thereof.

The gas source G64 is a gas source of TDMAB and is connected to the gas supply source 6 via the gas line L64. In the gas line L64, a mass flow controller M64 and a valve V64 are sequentially provided from a side of the gas source G64. The mass flow controller M64 controls a flow rate of TDMAB gas flowing in the gas line L64. The valve V64 performs supply and cutoff of the TDMAB gas to the gas supply path 6 by opening and closing operations thereof.

The film forming apparatus 1 includes the controller 100 and a storage 101. The controller 100 includes a CPU, a RAM, a ROM, and the like (none of which are illustrated), and causes the CPU to execute, for example, computer programs stored in the ROM or the storage 101, thereby comprehensively controlling the film forming apparatus 1. Specifically, the controller 100 controls operations of individual components of the film forming apparatus 1 by causing the CPU to execute a control program stored in the storage 101, so that a film forming processing or the like on the substrate W is performed.

Next, an example of an operation of the film forming apparatus 1 is described with reference again to FIG. 9. The film forming apparatus 1 performs, for example, the film forming method shown in FIGS. 1 and 2. In addition, the controller 100 may perform the film forming method shown in FIG. 5. In addition, a processing container 2 that performs step S102 and a processing container 2 that performs step S103 may be provided separately from each other. After the step S102 is performed inside a first processing container, the substrate W is transferred to a second processing container from the first processing container, and the step S103 may be performed inside the second processing container.

First, the controller 100 opens the gate valve 26, transfers the substrate W into the processing container 2 by a transfer mechanism, and places the substrate W on the stage 3. The substrate W is placed horizontally such that the surface WA faces upward. The controller 100 retracts the transfer mechanism from the processing container 2 and then closes the gate valve 26. Subsequently, the controller 100 heats the substrate W to a set temperature by the heating mechanism 34 of the stage 3 and adjusts the pressure in the processing container 2 to a set pressure by the pressure adjuster 23. For example, loading the substrate W into the processing container 2, and the like are included in step S101.

Subsequently, the controller 100 performs step S102a. In the step S102a, by opening the valves V64, V63, and V62, the TDMAB gas, the O₂ gas, and the Ar gas are simultaneously supplied into the processing container 2. At this time, the controller 100 closes the valve V61, so that the TiCl₄ gas is not supplied into the processing container 2.

Specific processing conditions of the step S102a are, for example, as follows.
Flow rate of the TDMAB gas: 1 sccm to 100 sccm
Flow rate of the O₂ gas: 100 sccm to 100,000 sccm
Flow rate of the Ar gas: 100 sccm to 100,000 sccm
Processing time: 1 sec to 1,200 sec
Processing temperature: 100 degrees C. to 450 degrees C.
Processing pressure: 3 Pa to 10,000 Pa

Subsequently, the controller 100 performs step S102b. In the step S102b, the valve 64 is closed. As this time, since the valves V63 and V62 are opened, the O₂ gas and the Ar gas are supplied into the processing container 2, and the TDMAB gas remaining in the processing container 2 is discharged to the exhaust pipe 22.

Specific processing conditions of the step S102b are, for example, as follows.
Flow rate of the O₂ gas: 100 sccm to 100,000 sccm
Flow rate of the Ar gas: 100 sccm to 100,000 sccm
Processing time: 1 sec to 60 sec
Processing temperature: 100 degrees C. to 450 degrees C.
Processing pressure: 3 Pa to 10,000 Pa

Subsequently, the controller 100 performs step S102c. In the step S102c, plasma is generated by the plasma generator 51, thereby plasmarizing the O₂ gas. Accordingly, B (boron) contained in the adsorbed TDMAB gas is oxidized so that for example, a BO film is formed. The BO film is formed more thickly on the top surface of the protrusion WA1 than on the inside of the recess WA2. The BO film is formed along the protrusion-recess pattern and is formed not only on the top surface of the protrusion WA1 but also inside the recess WA2. Specific processing conditions of the step S102c are the same as the processing conditions of the step S102b except for the generation of plasma, and therefore, descriptions are omitted.

Subsequently, the controller 100 performs step S102d. In the step S102d, the generation of plasma is stopped. As this time, since the valves V63 and V62 are opened, the O₂ gas and the Ar gas are supplied into the processing container 2, so that the plasmarized gas remaining in the processing container 2 is discharged to the exhaust pipe 22. Specific processing conditions of the step S102d are the same as the processing conditions of the step S102b, and therefore, descriptions are omitted.

Subsequently, in step S102e, the controller 100 checks whether or not the steps S102a to S102d have been performed K (K is a natural number of 1 or more) times. If a number of times the steps S102a to S102d are performed is less than K times (“NO” in step S102e), the controller 100 performs the steps S102a to S102d again. On the other hand, if the number of times the steps S102a to S102d are performed reaches K times (“YES” in step S102e), the controller 100 performs the step S103.

Subsequently, the controller 100 performs step S103a. In the step S103a, by opening the valves V61, V62, and V63, the TiCl₄ gas, the Ar gas, and the O₂ gas are simultaneously supplied into the processing container 2. At this time, since the controller 100 closes the valve V64, the TDMAB gas is not supplied into the processing container 2.

Specific processing conditions of the step S103a are, for example, as follows.
Flow rate of the TiCl₄ gas: 1 sccm to 500 sccm
Flow rate of the Ar gas: 100 sccm to 100,000 sccm
Flow rate of the O₂ gas: 100 sccm to 100,000 sccm
Processing time: 0.1 sec to 30 sec
Processing temperature: 100 degrees C. to 450 degrees C.
Processing pressure: 3 Pa to 10,000 Pa

Subsequently, the controller 100 performs step S103b. In the step S103b, the valve V61 is closed. At this time, since the valves V62 and V63 are opened, the Ar gas and the O₂ gas are supplied into the processing container 2, so that the TiCl₄ gas remaining in the processing container 2 is discharged to the exhaust pipe 22.

Specific processing conditions of the step S103b are, for example, as follows.
Flow rate of the Ar gas: 100 sccm to 100,000 sccm
Flow rate of the O₂ gas: 100 sccm to 100,000 sccm
Processing time: 0.1 sec to 30 sec
Processing temperature: 100 degrees C. to 450 degrees C.
Processing pressure: 3 Pa to 10,000 Pa

Subsequently, the controller 100 performs step S103c. In the step S103c, plasma is generated by the plasma generator 51, thereby plasmarizing the 02 gas. Accordingly, the adsorbed TiCl₄ gas is oxidized, so that, for example, a TiO film is formed. The TiO film is hardly formed on the top surface of the protrusion WA1 due to hindrance to film formation by the BO film, and is formed more thickly inside the recess WA2 than on the top surface of the protrusion WA1. Specific processing conditions of the step S103c are the same as the processing conditions of the step S103b other than the generation of plasma, and therefore, descriptions are omitted.

Subsequently, the controller 100 performs step S103d. In the step S103d, the generation of plasma is stopped. At this time, since the valves V62 and V63 are opened, the Ar gas and the 02 gas are supplied into the processing container 2, so that the plasmarized gas remaining in the processing container 2 is discharged to the exhaust pipe 22. Specific processing conditions of the step S103d are the same as the processing conditions of the step S103b, and therefore, descriptions are omitted.

Subsequently, in step S103e, the controller 100 checks whether or not the steps S103a to S103d have been performed L (L is a natural number of 1 or more) times. If a number of times the steps S103a to S103d are performed is less than L times (“NO” in step S103e), the controller 100 performs the steps S103a to S103d again. On the other hand, if the number of times the steps S103a to S103d are performed reaches L times (“YES” in step S103e), the controller 100 performs step S105. Further, the controller 100 may perform step S104 after the step S103 and before the step S105.

Subsequently, in the step S105, the controller 100 checks whether or not the first cycle has been performed N times. If a number of times the first cycle is performed is less than N times (“NO” in step S105), the controller 100 performs the first cycle again. On the other hand, if the number of times the first cycle is performed reaches N times (“YES” in step S105), the controller 100 ends this processing. Thereafter, the controller 100 opens the gate valve 26 and takes the substrate W out of the processing container 2 by the transfer mechanism. The controller 100 retracts the transfer mechanism from the processing container 2 and then closes the gate valve 26.

### EMBODIMENTS

Next, embodiments and the like are described. The following Example 1 is a comparative example, and the following Examples 2 and 3 are embodiments.

### Example 1

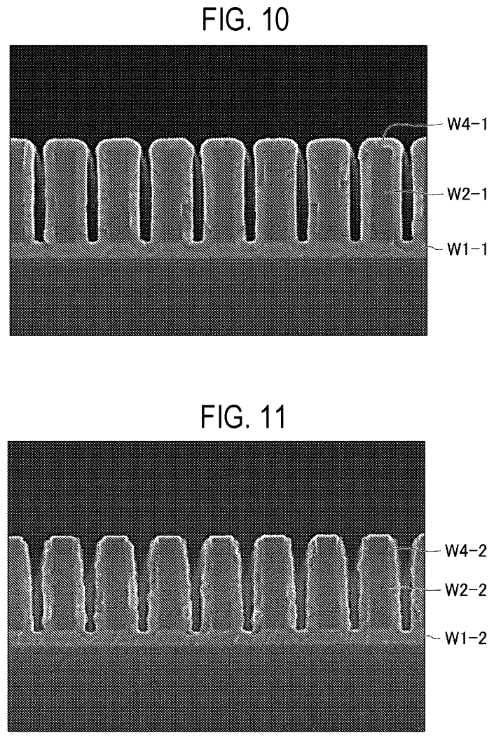

In Example 1, as illustrated in FIG. 10, by preparing a substrate in which a SiN film W1-1 and an amorphous Si film W2-1 were sequentially formed in this order on a Si substrate, and an opening pattern was formed in the amorphous Si film W2-1, the steps 103a to S103d were performed in processing conditions shown in Table 1.

TABLE 1

| | | | | | Temper- | | |
|---|---|---|---|---|---|---|---|
| | | | | | ature | | |
| | | Time | Supplied | | [degrees | | |
| | Step | [sec] | Gas | RF | C.] | L, N | |
| Example 1 | S103a | 0.5 | TiCl₄ + | OFF | 300 | L = | N = 1 |
| | | | Ar + O₂ | | | 300 | |
| | S103b | 1.0 | Ar + O₂ | OFF | | | |
| | S103c | 0.4 | Ar + O₂ | ON | | | |
| | S103d | 0.1 | Ar + O₂ | OFF | | | |

In Table 1, “ON” of “RF” means plasmarizing a gas by high-frequency power. “OFF” of “RF” means not performing the plasmarization of the gas. In the following Tables 2 and 3, these are the same. As shown in Table 1, the gas was plasmarized in S103c.

As shown in Table 1, in Example 1, the step S102 was not performed. Since a film containing boron was not formed in the step S102, a TiN film W4-1 was uniformly formed both on a top surface of a protrusion and inside a recess in the step S103 as illustrated in FIG. 10.

### Example 2

In Example 2, as illustrated in FIG. 11, by preparing a substrate in which a SiN film W1-2 and an amorphous Si film W2-2 were sequentially formed in this order on a Si substrate, and an opening pattern was formed in the amorphous Si film W2-2, the steps S102a, 102c, and S102d and the steps S103a to S103d were performed in processing conditions shown in Table 2. As shown in Table 2, gases were plasmarized in S5102c and S5103c.

TABLE 2

| | | Time | | | Temperature | | |
|---|---|---|---|---|---|---|---|
| | Step | [sec] | Supplied Gas | RF | [degrees C.] | K, L, N | |
| Example 2 | S102a | 1.0 | TDMAB + Ar + O₂ | OFF | 300 | K = 1 | N = 1 |
| | S102c | 300 | TDMAB + Ar + O₂ | ON | | | |
| | S102d | 1.0 | Ar + O₂ | OFF | | | |
| | S103a | 0.5 | TiCl₄ + Ar + O₂ | OFF | 300 | L = 300 | |
| | S103b | 1.0 | Ar + O₂ | OFF | | | |
| | S103c | 0.4 | Ar + O₂ | ON | | | |
| | S103d | 0.1 | Ar + O₂ | OFF | | | |

As shown in Table 2, unlike Example 1, the step S102 was performed in Example 2. As a result, a BO film was able to be formed in the step S102, and a TiO film W4-2 was formed more thickly inside a recess than on a top surface of a protrusion in the step S103 as illustrated in FIG. 11. The TiO film W4-2 was hardly formed on the top surface of the protrusion.

### Example 3

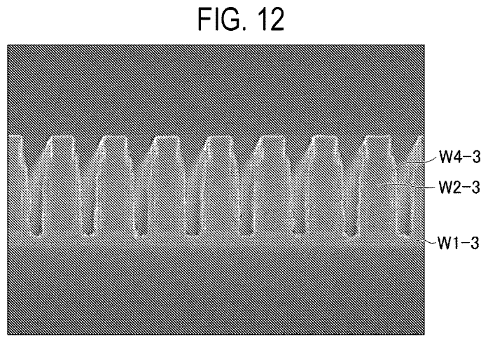

In Example 3, as illustrated in FIG. 12, by preparing a substrate in which a SiN film W1-3 and an amorphous Si film W2-3 were sequentially formed in this order on a Si substrate, and an opening pattern was formed in the amorphous Si film W2-3, the steps S102a, S102c, and S102d and the steps S103a to S103d were performed in processing conditions shown in Table 3. As shown in Table 3, gases were plasmarized in S102c and S103c.

TABLE 3

| | | Time | | | Temperature | | |
|---|---|---|---|---|---|---|---|
| | Step | [sec] | Supplied Gas | RF | [degrees C.] | K, L, N | |
| Example 3 | S102a | 1.0 | TDMAB + Ar + O₂ | OFF | 300 | K = 1 | N = 1 |
| | S102c | 600 | TDMAB + Ar + O₂ | ON | | | |
| | S102d | 1.0 | Ar + O₂ | OFF | | | |
| | S103a | 0.5 | TiCl₄ + Ar + O₂ | OFF | 300 | L = 300 | |
| | S103b | 1.0 | Ar + O₂ | OFF | | | |
| | S103c | 0.4 | Ar + O₂ | ON | | | |
| | S103d | 0.1 | Ar + O₂ | OFF | | | |

As shown in Table 3, unlike Example 1, the step S102 was performed in Example 3. As a result, a BO film was able to be formed in the step S102, and a TiO film W4-3 was formed more thickly inside a recess than on a top surface of a protrusion in the step S103 as illustrated in FIG. 12. The TiO film W4-3 was hardly formed on the top surface of the protrusion.

In the above, embodiments of the film forming method and the film forming apparatus according to the present disclosure have been described, but the present disclosure is not limited to the embodiments and the like. Various changes, modifications, substitutions, additions, deletions, and combinations are possible within the scope of claims. These are naturally considered as being within the technical scope of the present disclosure.

According to the present disclosure in some embodiments, it is possible to form a film inside a recess of a substrate surface.

This application is based upon and claims the benefit of priority from Japanese Patent Application No. 2023-010861, filed on Jan. 27, 2023, the entire contents of which are incorporated herein by reference.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method, comprising:
preparing a substrate having a protrusion and a recess recessed from a top surface of the protrusion in a surface of the substrate;
forming a first film containing boron more thickly on the top surface of the protrusion than on an inside of the recess; and
after the forming of the first film, alternately or simultaneously supplying a raw material gas containing halogen and an element X other than the halogen and a reaction gas reacting with an adsorbate of the raw material gas to the surface of the substrate, thereby forming a second film containing the element X more thickly inside the recess than on the top surface of the protrusion.

2. The film forming method of claim 1, wherein the first film is formed not only on the top surface of the protrusion but also inside the recess, and is formed more thickly on the top surface of the protrusion than on the inside of the recess.

3. The film forming method of claim 2, wherein a first cycle including the forming of the first film and the forming of the second film is repeated a plural number of times.

4. The film forming method of claim 1, comprising etching a portion of the second film.

5. The film forming method of claim 4, wherein a second cycle including the forming of the first film, the forming of the second film, and the etching of the second film is repeated a plural number of times.

6. The film forming method of claim 1, wherein the element X includes a metal element.

7. The film forming method of claim 1, wherein the element X includes a transition metal element.

8. The film forming method of claim 1, wherein the element X includes a semiconductor element.

9. The film forming method of claim 1, wherein the forming of the second film includes alternately supplying the raw material gas and the reaction gas, and the reaction gas is supplied after being plasmarized.

10. The film forming method of claim 1, wherein, in the forming of the second film, a processing that sequentially includes supplying the raw material gas containing an element X1 as the element X, supplying the raw material gas containing an element X2, which is different from the element X1, as the element X, and supplying the reaction gas in this order is performed once or more.

11. The film forming method of claim 1, wherein, in the forming of the second film, a processing that sequentially includes supplying the raw material gas containing an element X1 as the element X and supplying the reaction gas, in this order, is performed once or more, and a processing that sequentially includes supplying the raw material gas containing an element X2, which is different from the element X1, as the element X, and supplying the reaction gas, in this order, is performed once or more.

12. A film forming apparatus, comprising:
a processing container configured to accommodate a substrate having a protrusion and a recess in a surface of the substrate;
a holder configured to hold the substrate inside the processing container;
a gas supply configured to supply a gas to the surface of the substrate held by the holder; and
a controller configured to control the gas supply,
wherein the controller controls to perform the film forming method of claim 1.

13. A film forming apparatus, comprising:
a processing container configured to accommodate a substrate having a protrusion and a recess in a surface of the substrate;
a holder configured to hold the substrate inside the processing container;
a gas supply configured to supply a gas to the surface of the substrate held by the holder;
a plasma generator configured to plasmarize the gas; and
a controller configured to control the gas supply and the plasma generator,
wherein the controller controls to perform the film forming method of claim 9.

14. The film forming method of claim 1, wherein a first cycle including the forming of the first film and the forming of the second film is repeated a plural number of times.
